(19) United States
(12) Patent Application Publication
(10) Pub. No.: US 2024/0188414 A1
(43) Pub. Date: Jun. 6, 2024

(54) CONJUGATED ANTHRADITHIOPHENE TERPOLYMERS AND PHOTOVOLTAIC DEVICES CONTAINING THEM

(71) Applicant: ENI S.P.A., Roma (IT)

(72) Inventors: Gabriele BIANCHI, Novara (IT); Fabio MELCHIORRE, Novara (IT); Fiorenza SIMONE, Novara (IT)

(21) Appl. No.: 18/549,402

(22) PCT Filed: Mar. 7, 2022
(86) PCT No.: PCT/IB2022/051983

§ 371 Date: Sep. 7, 2023

(30) Foreign Application Priority Data
Mar. 8, 2021 (IT) 102021000005339

(51) Int. Cl. H10K 85/10; C08G 61/12

(52) U.S. Cl. CPC H10K 85/113; C08G 61/126; C08G 2261/1426; C08G 2261/146; C08G 2261/3243; C08G 2261/344; C08G 2261/91

(57) ABSTRACT

A conjugated anthradithiophene terpolymer having general formula (I):

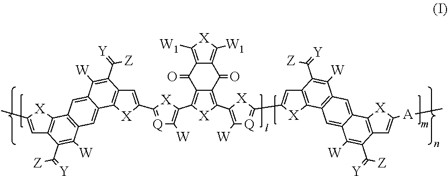

wherein
Q, equal or different from each other, represent a nitrogen atom;
W, equal or different from each other, represent a hydrogen atom;
W₁, equal or different from each other, represent a hydrogen atom;
X, equal or different from each other, represent a sulfur atom, an oxygen atom, a selenium atom;
Y, equal or different from each other, represent an oxygen atom, a sulfur atom;
Z, equal or different from each other, are selected from amino groups —N—R₂R₃ wherein R₂represents a hydrogen atom;
A represents an electron-acceptor group; an electron-donor group;
l and m, equal or different from each other, represent an integer ranging from 1 to 9; and
n is an integer ranging from 10 to 500.

### CROSS-REFERENCE TO RELATED APPLICATIONS

This application is a 35 U.S.C. § 371 National Stage patent application of PCT/IB2022/051983 filed 7 Mar. 2022, which claims the benefit of Italian patent application 102021000005339 filed 8 Mar. 2021, the disclosures of which are incorporated herein by reference in their entirety.

### TECHNICAL FIELD

The present disclosure relates to conjugated anthradithiophene terpolymers.

More specifically, the present disclosure relates to a conjugated anthradithiophene terpolymer disubstituted on the anthracene ring.

Said conjugated anthradithiophene terpolymer can be advantageously used in the construction of photovoltaic devices (or solar devices) such as, for example, photovoltaic cells (or solar cells), photovoltaic modules (or solar modules), either on a rigid support or on a flexible support.

### BACKGROUND

Photovoltaic devices (or solar devices) are devices capable of converting the energy of a light radiation into electricity. Currently, most photovoltaic devices (or solar devices) usable for practical applications, exploit the chemical-physical properties of photoactive materials of the inorganic type, in particular high purity crystalline silicon. Due to the high production costs of silicon, however, scientific research has long been directing its efforts towards the development of alternative organic-type materials having a conjugated, oligomeric or polymeric structure, in order to obtain organic photovoltaic devices (or solar devices) such as, for example, organic photovoltaic cells (or solar cells). In fact, unlike high purity crystalline silicon, said organic-type materials are characterized by a relative ease of synthesis, a low production cost, a reduced weight of the relative organic photovoltaic devices (or solar devices), as well as allowing said organic-type materials to be recycled at the end of the life cycle of the organic photovoltaic device (or solar device) in which they are used.

The above mentioned advantages make the use of said organic-type materials energetically and economically attractive despite any lower efficiencies (η) of the organic photovoltaic devices (or solar devices) thus obtained compared to inorganic photovoltaic devices (or solar devices).

The operation of the organic photovoltaic devices (or solar devices) such as, for example, organic photovoltaic cells (or solar cells), is based on the combined use of an electron-acceptor compound and an electron-donor compound. In the state of the art, the electron-acceptor compounds most commonly used in organic photovoltaic devices (or solar devices) are fullerene derivatives, in particular PC61BM (6,6-phenyl-C₆₁-methyl ester butyric) or PC71BM (6,6-phenyl-C₇₁-methyl ester butyric), which led to the greatest efficiencies when mixed with electron-donor compounds selected from π-conjugated polymers such as, for example, polythiophenes (η>5%), polycarbazoles (η>6%), derivatives of poly(thienotiophene)benzodithiophene (PTB) (η>8%).

It is known that the elementary process of converting light into electric current in an organic photovoltaic cell (or solar cell) takes place through the following steps:
1. absorption of a photon by the electron-donor compound with the formation of an exciton, i.e. a pair of carriers of the charge “electron-electronic gap (or hole)”;
2. diffusion of the exciton in a region of the electron-donor compound up to the interface with the electron-acceptor compound;
3. dissociation of the exciton in the two charge carriers: electron (−) in the accepting phase (i.e. in the electron-acceptor compound) and electronic gap [(or hole) (+)] in the donor phase (i.e. in the electron-donor compound);
4. transport of the charges thus formed to the cathode (electron through the electron-acceptor compound) and to the anode [electronic gap (or hole) through the electron-donor compound], with generation of an electric current in the circuit of the organic photovoltaic cell (or solar cell). The photoabsorption process with formation of the exciton and subsequent transfer of the electron to the electron-acceptor compound involves the excitation of an electron from the HOMO (“Highest Occupied Molecular Orbital”) to the LUMO (“Lowest Unoccupied Molecular Orbital”) of the electron-donor compound and, subsequently, the passage therefrom to the LUMO of the electron-acceptor compound.

Since the efficiency of an organic photovoltaic cell (or solar cell) depends on the number of free electrons that are generated by dissociation of excitons which is in turn directly correlated to the number of absorbed photons, one of the structural characteristics of the electron-donor compounds that mostly affects this efficiency is the difference in energy existing between the HOMO and LUMO orbitals of the electron-donor compound, that is the so-called “band-gap”. In particular, the maximum value of the wavelength at which the electron-donor compound is able to effectively harvest and convert photons into electricity, i.e. the so-called “light harvesting” or “photon harvesting” process, depends on this difference. In order to obtain acceptable electric currents, the “band gap”, that is the difference in energy between HOMO and LUMO of the donor compound, on the one hand must not be too high so as to allow the absorption of the largest number of photons and on the other hand it must not be too low because it could decrease the voltage to the electrodes of the device.

In the simplest way of operating, organic photovoltaic cells (or solar cells) are manufactured by introducing between two electrodes, usually consisting of indium-tin oxide (ITO) (anode) and aluminium (Al) (cathode), a thin layer (about 100 nanometres) of a mixture of the electron-acceptor compound and the electron-donor compound (an architecture known as “bulk heterojunction”). Generally, in order to make a layer of this type, a solution of the two compounds is prepared and, subsequently, a photoactive film is created on the anode [indium-tin oxide (ITO)] starting from said solution, using suitable deposition techniques such as, for example, “spin-coating”, “spray-coating”, “ink-jet printing”, and the like. Finally, the counter electrode [i.e. the aluminium cathode (Al)] is deposited on the dried film. Optionally, other additional layers can be introduced between the electrodes and the photoactive film, which layers are capable of performing specific functions of an electrical, optical, or mechanical nature.

Generally, in order to facilitate the achievement of the anode [indium-tin oxide (ITO)] by the electronic gaps (or holes) and at the same time to block the transport of electrons, thus improving the harvest of charges by the electrode and inhibiting the recombination phenomena, before creating the photoactive film starting from the mixture of the acceptor compound and the donor compound as described above, a film is deposited starting from an aqueous suspension of PEDOT:PSS [poly (3,4-ethylenedioxythiophene)polystyrene sulfonate], using suitable deposition techniques such as, for example, “spin-coating”, “spray-coating”, “ink-jet printing”, and the like.

The electron-donor compound most commonly used in the realization of organic photovoltaic cells (or solar cells) is the regioregular poly(3-hexylthiophene) (P3HT). This polymer has optimal electronic and optical characteristics (good values of the HOMO and LUMO orbitals, good molar absorption coefficient), good solubility in the solvents that are used to manufacture photovoltaic cells (or solar cells) and a moderate mobility of the electronic gaps.

Other examples of polymers that can be advantageously used as electron-donor compounds are: the PCDTBT polymer {poly[N-9″-heptadecanil-2,7-carbazole-alt-5,5-(4′,7′-di-2-thienyl-2′,1′,3′-benzothiadiazole]}, the PCPDTBT polymer {poly[2,6-(4,4-bis-(2-ethylhexyl)-4H-cyclopenta[2,1-b;3,4-b′]dithiophene)-alt-4,7(2,1,3-benzothiadiazole)]}.

Electron-donor compounds containing benzodithiophenic units are also known which have a structure similar to poly(3-hexylthiophene) (P3HT) in which, however, the thiophenic units are planarized by benzene rings. This feature, in addition to reducing the oxidation potential of said electron-donor compounds, improves their stability in the air and ensures their rapid packaging and, consequently, a high molecular order, during the realization of the photoactive film: this results in excellent transport properties of charges [electrons or electronic gaps (holes)]. Consequently, the use of electron-donor compounds containing benzodithiophenic units can allow the realization of photovoltaic devices with better performances.

For example, electron-donor compounds containing benzodithiophenic units are described by Huo L. et al. in the article: “Synthesis of a polythieno[3,4-b]thiophene derivative with a low-lying HOMO level and its application in polymer solar cells”, “Chemical Communication” (2011), Vol 47, pages 8850-8852. Said article describes the preparation of a polythieno[3,4-b]thiophene derivative by copolymerization between a planar benzodithiophene having a low HOMO value with a thieno[3,4-b]thiophenic unit.

Benzodithiophene and/or the isomers thereof [e.g., benzo[1,2-b:4,5-b′]dithiophene or (BDT) and benzo[2,1-b:3,4-b]dithiophene or (BDP)], are known to be compounds of significant interest whose synthesis has been the subject of numerous researches.

Generally, the electron-donor materials used in high efficiency photovoltaic cells are almost exclusively represented by polymers in which an electron-rich unit alternates with an electron-poor unit. Further details relating to said polymers can be found, for example, in the following articles: Yu L. et al., “How to design low bandgap polymers for highly efficient organic solar cells”, “Materials Today” (2014), Vol. 17, No. 1, pages 11-15; You W. et al.: “Structure-Property Optimizations in Donor Polymers via Electronics, Substituents, and Side Chains Toward High Efficiency Solar Cells”, “Macromolecular Rapid Communications” (2012), Vol. 33, pages 1162-1177; Having a E. E. et al.: “A new class of small band gap organic polymer conductors”, “Polymer Bulletin” (1992), Vol. 29, pages 119-126.

However, said electron-donor polymers are not always optimal. In fact, since the flow of photons of the solar radiation that reaches the surface of the earth is maximum for energy values around 1.8 eV (corresponding to radiations having a wavelength of about 700 nm), due to the high “band-gap” values (generally greater than 2 eV-3 eV) that characterize many of the aforementioned electron-donor polymers, the so-called “light harvesting” or “photon harvesting” process is not very efficient and only a part of the total solar radiation is converted into electricity.

In order to improve the yield of the so-called “light harvesting” or “photon harvesting” process and, consequently, the efficiency of organic photovoltaic devices (or solar devices), it is therefore essential to identify new electron-donor polymers capable of capturing and converting the wavelengths of solar radiation having lower energy, i.e. electron-donor polymers characterized by lower “band-gap” values than those of the polymers typically used as electron-donors.

To this end, efforts have been made in the art to identify electron-donor polymers having a low band gap value (i.e. a “band gap” value lower than 2 eV).

For example, one of the most commonly used strategies for obtaining electron-donor polymers having a low “band-gap” value is the synthesis of alternate conjugated polymers comprising electron-rich units (donor) and electron-poor units (acceptor). A summary of this type is described, for example by Chen J. et al. in the article “Development of Novel Conjugated Donor Polymers for High-Efficiency Bulk-Heterojunction Photovoltaic Devices”, “Account of Chemical Research” (2009), Vol. 42(11), pages 1709-1718.

Anthradithiophene derivatives are also known which can be used both in the construction of photovoltaic devices (or solar devices), and in the construction of Organic Thin Film Transistors (“OTFT”), or of Organic Field Effect Transistor (“OFET”), or of Organic Light-Emitting Diodes (“OLEDs”).

For example, Pietrangelo A. et al. in the article “Conjugated Thiophene-Containing Oligoacenes Through Photocyclization: Bent Acenedithiophenes and a Thiahelicene”, “Journal of Organic Chemistry” (2009), Vol. 74, pages 4918-4926 describe the preparation of anthraditiophenic “bents” (BADTs) by oxidative photocycling of 2,5-dithienyl-1,4-distyrylbenzene. The aforesaid anthradithiophenes are said to be advantageously usable in the construction of Organic Thin Film Transistors (“OTFTs”).

Quinton C. et al. in the article “Evaluation of semiconducting molecular thin films solution-processed via the photoprecursor approach: the case of hexyl-substituted thienoanthracenes”, “Journal of Materials Chemistry C” (2015), Vol. 3, pages 5995-6005, describe the use of thienoanthracenes disubstituted with hexyl groups on the thiophenic ring as semi-conductors in the preparation of thin films by depositing a solution containing a photoprecursor selected from said disubstituted thienoanthracenes. Said disubstituted thienoanthracenes can be synthesized through various processes: for example, said disubstituted thienoanthracenes can be synthesized through a cyclization reaction catalysed by indium, or through a photochemical cyclization reaction of 2,5-bis(2-thienyl)-1,4-divinylbenzene.

Wu J. S. et al. in the article “New Angular-Shaped and Isomerically Pure Anthradithiophene with Lateral Aliphatic Side Chains for Conjugated Polymers: Synthesis, Characterization, and Implications for Solution-Processed Organic Field-Effect Transistors and Photovoltaics”, “Chemistry of Materials” (2012), Vol. 24, pages 2391-2399, describe alternated copolymers such as poly(anthradithiophene-alt-bithiophene) (PaADTDPP) and poly(anthradithiophene-alt-bithiophene) (PaADTDPP) rich in thiophene (PaADTT). Said alternated copolymers can be prepared by means of a double benzoannulation via Suzuki coupling starting from compounds of the benzene-thiophene dibromodiaryl type. The aforesaid alternated copolymers are said to be advantageously usable in the construction of photovoltaic cells (or solar cells) and of Organic Field Effect Transistors (“OFETs”).

The processes described in the aforesaid documents relating to anthradithiophene derivatives, however, do not allow to obtain anthradithiophene derivatives functionalised directly on the anthracenic ring.

Anthradithiophene derivatives functionalised directly on the anthracene ring are described in international patent application WO 2019/175367 on behalf of the Applicant.

The above-mentioned international patent application WO 2019/175367 describes, in fact, an anthradithiophene derivative having general formula (I):

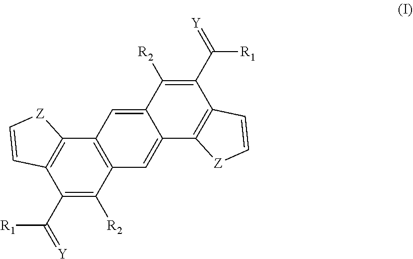

wherein:
Z, equal or different from each other, preferably equal to each other, represent a sulfur atom, an oxygen atom, a selenium atom;
Y, equal or different from each other, preferably equal to each other, represent a sulfur atom, an oxygen atom, a selenium atom;
R₁, equal to or different from each other, preferably equal to each other, are selected from amino groups —N—R₃R₄ wherein R₃ represents a hydrogen atom, or is selected from C₁-C₂₀ alkyl groups, preferably C₂-C₁₀, linear or branched, or is selected from optionally substituted cycloalkyl groups and R₄ is selected from C₁-C₂₀ alkyl groups, preferably C₂-C₁₀, linear or branched, or is selected from optional substituted cycloalkyl groups; or they are selected from C₁-C₃₀ alkoxyl groups, preferably C₂-C₂₀, linear or branched; or they are selected from R₅—O—[CH₂—CH₂—O]ₙ-polyethyleneoxy groups, wherein R₅ is selected from C₁-C₂₀ alkyl groups, preferably C₂-C₁₀, linear or branched, and n is an integer ranging from 1 to 4; or they are selected from —R₆—OR₇ groups wherein R₆ is selected from C₁-C₂₀ alkylene groups, preferably C₂-C₁₀, linear or branched and R₇ represents a hydrogen atom, or is selected from C₁-C₂₀ alkyl groups, preferably C₂-C₁₀, linear or branched, or is selected from R₅—[—OCH₂—CH₂—O]ₙ-polyethyleneoxy groups wherein R₅ has the same meanings reported above and n is an integer ranging from 1 to 4; or they are selected from —S—R thiol groups wherein R is selected from C₁-C₂₀ alkyl groups, preferably C₂-C₁₀, linear or branched;
R₂, equal or different from each other, preferably equal to each other, represent a hydrogen atom; or they are selected from C₁-C₂₀ alkyl groups, preferably C₂-C₁₀, linear or branched; or they are selected from —COR₉ groups wherein R₉ is selected from C₁-C₂₀ alkyl groups, preferably C₂-C₁₀, linear or branched; or they are selected from —COOR₁₀ groups wherein R₁₀ is selected from C₁-C₂₀ alkyl groups, preferably C₂-C₁₀, linear or branched; or they are selected from optional substituted aryl groups; or are selected from optional substituted heteroaryl groups.
The aforesaid anthradithiophene derivative is said to be advantageously usable as a monomeric unit in the synthesis of electron-donor polymers having a low “band gap” value (i.e., a band gap value of less than 2 eV) which in turn can be used in the construction of photovoltaic devices (or solar devices) such as, for example, photovoltaic cells (or solar cells), photovoltaic modules (or solar modules), either on a rigid support or on a flexible support. Furthermore, said polymers are also said to be advantageously used in the construction of Organic Thin Film Transistors (“OTFTs”), Organic Field Effect Transistors (“OFETs”), or Organic Light-Emitting Diodes (“OLEDs”).

Since organic photovoltaic devices (or solar devices) are still of great interest, the study of new electron-donor polymers having a low band gap (i.e. a band gap value below 2 eV) is also of great interest.

### SUMMARY

The Applicant was therefore faced with the problem of finding electron donor polymers, in turn usable in the construction of photovoltaic devices (or solar devices), having a low “band gap” value (i.e. a “band gap” value lower than 2 eV).

The Applicant has now found a conjugated anthradithiophene terpolymer disubstituted on the anthracene ring having a low “band gap” value (i.e., a “band gap” value below 2 eV) which may be advantageously usable in the construction of organic photovoltaic devices (or solar devices), such as, for example, photovoltaic cells (or solar cells), photovoltaic modules (or solar modules), either on a rigid support, or on a flexible support. In particular, said conjugated anthradithiophene terpolymer makes it possible to obtain inverted polymer photovoltaic cells (or solar cells) with good performance, in particular in terms of photoelectric conversion efficiency (PCE) (η. Furthermore, said conjugated anthradithiophene terpolymer shows good processability, particularly at room temperature (25° C.).

Therefore, the present disclosure is a conjugated anthradithiophene terpolymer having general formula (I):

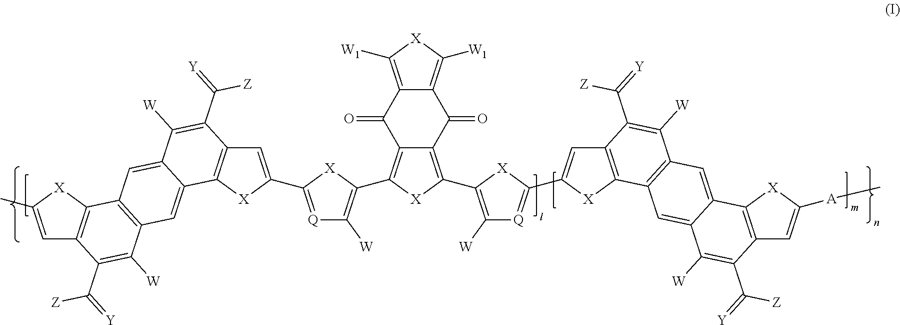

wherein:
Q, equal or different from each other, represent a nitrogen atom; or they are selected from C—R₁ groups wherein R₁ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
W, equal or different from each other, represent a hydrogen atom; or they are selected from C₁-C₂₀ alkyl groups, preferably C₂-C₁₀, linear or branched;
W₁, equal or different from each other, represent a hydrogen atom; or they are selected from C₁-C₂₀ alkyl groups, preferably C₂-C₁₀, linear or branched;
X, equal or different from each other, represent a sulfur atom, an oxygen atom, a selenium atom;
Y, equal or different from each other, represent an oxygen atom, a sulfur atom;
Z, equal or different from each other, are selected from amino groups —N—R₂R₃ wherein R₂ represents a hydrogen atom, or is selected from C₁-C₂₀ alkyl groups, preferably C₂-C₁₀, linear or branched, or is selected from optionally substituted cycloalkyl groups and R₃ is selected from C₁-C₂₀ alkyl groups, preferably C₂-C₁₀, linear or branched, or is selected from optionally substituted cycloalkyl groups; or they are selected from —O—R₄ groups wherein R₄ is selected from C₁-C₃₀ alkyl groups, preferably C₂-C₂₄, linear or branched, optionally substituted cycloalkyl groups, optionally substituted aryl groups, optionally substituted heteroaryl groups; or they are selected from R₅—O—[CH₂—CH₂—O]ₙ₁-polyethyleneoxy groups wherein R₅ is selected from C₁-C₂₀ alkyl groups, preferably C₂-C₁₀, linear or branched, and n1 is an integer ranging from 1 to 4; or they are selected from —R₆—OR₇ groups wherein R₆ is selected from C₁-C₂₀ alkylene groups, preferably C₂-C₁₀, linear or branched and R₇ represents a hydrogen atom or is selected from C₁-C₂₀ alkyl groups, preferably C₂-C₁₀, linear or branched; or they are selected from R₅—[—OCH₂—CH₂—]ₙ₁-polyethyleneoxy groups wherein R₅ has the same meanings reported above and n1 is an integer ranging from 1 to 4; or they are selected from R—S-thiol groups wherein R is selected from C₁-C₂₀ alkyl groups, preferably C₂-C₁₀, linear or branched;
A represents an electron-acceptor group; an electron-donor group; or is selected from optionally substituted aryl groups, optionally substituted heteroaryl groups;
l and m, equal or different from each other, represent an integer ranging from 1 to 9, preferably 1 is 1 or 2 and m is 8 or 9;
n is an integer ranging from 10 to 500, preferably ranging from 20 to 300.

In accordance with an embodiment of the present disclosure, said group A can be selected, for example, among the groups shown in Table 1.

TABLE 1

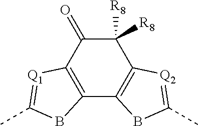

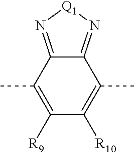

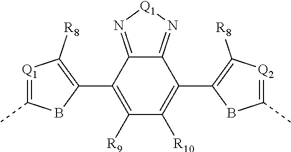

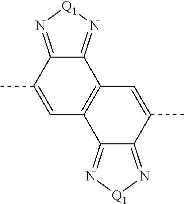

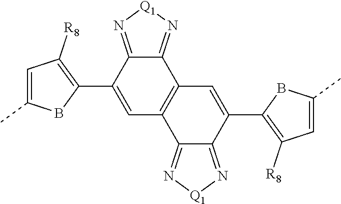

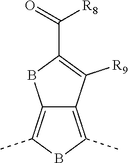

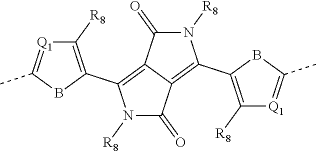

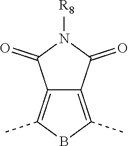

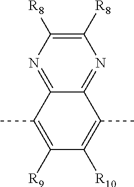

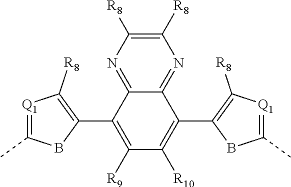

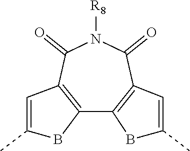

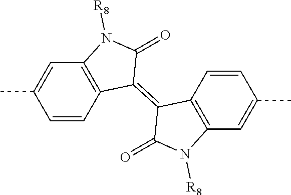

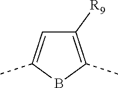

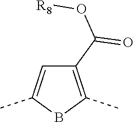

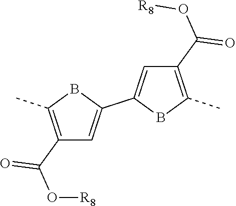

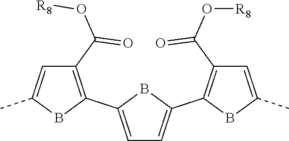

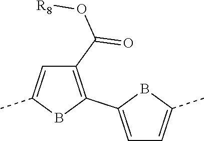

wherein:
B represents a sulfur atom, an oxygen atom, a selenium atom, or is selected from N—R₁₁ groups wherein R₁₁ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
Q₁ and Q₂, equal or different from each other, represent a nitrogen atom, a sulfur atom, an oxygen atom, a selenium atom; or they are selected from C—R₁₂ groups wherein R₁₂ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
R₈, equal or different from each other, are selected from C₁-C₂₀ alkyl groups, preferably C₂-C₁₀, linear or branched, optionally halogenated, optionally substituted cycloalkyl groups, optionally substituted aryl groups, optionally substituted heteroaryl groups, C₁-C₂₀ alkoxyl groups, preferably C₂-C₁₀, linear or branched; or they are selected from polyethyleneoxy groups R₁₃—[—OCH₂—CH₂—]ₙ— wherein R₁₃ is selected from C₁-C₂₀ alkyl groups, preferably C₂-C₁₀, linear or branched, and n is an integer ranging from 1 to 4; or they are selected from —R₁₄—OR₁₄ groups wherein R₁₄ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups; or they are selected from —COO—R₁₅ groups wherein R₁₅ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups; or represent a —CHO group, or a cyano group (—CN);
R₉ and R₁₀, equal or different from each other, represent a hydrogen atom, a fluorine atom, a chlorine atom; or they are selected from C₁-C₂₀ alkyl groups, preferably C₂-C₁₀, linear or branched, optionally substituted cycloalkyl groups, optionally substituted aryl groups, C₁-C₂₀ alkoxyl groups, preferably C₂-C₁₀, linear or branched; or they are selected from polyethyleneoxy groups R₁₃—[—OCH₂—CH₂—]ₙ— wherein R₁₃ has the same meanings reported above and n is an integer ranging from 1 to 4; or they are selected from —R₁₄—OR₁₄ groups wherein R₁₄ has the same meanings reported above; or they are selected from —COR₁₅ groups wherein R₁₅ has the same meanings reported above; or they are selected from —COO—R₁₅ groups wherein R₁₅ has the same meanings reported above; or they represent a —CHO group, or a cyano group (—CN);
or R₉ and R₁₀, may optionally be bound together so as to form, together with the carbon atoms to which they are bound, a saturated, unsaturated, or aromatic, polycyclic cycle or system containing from 3 to 14 carbon atoms, preferably from 4 to 6 carbon atoms, optionally containing one or more heteroatoms such as, for example, oxygen, sulfur, nitrogen, silicon, phosphorus, selenium.

In accordance with an embodiment of the present disclosure, in said general formula (I):
Q represents a C—R₁ group wherein R₁ represents a hydrogen atom;
W, equal to each other, represent a hydrogen atom;
W₁, equal to each other, represent a C₁-C₂₀ alkyl group, linear or branched, preferably are a 2-ethylhexyl group;
X, equal to each other, represent a sulfur atom;
Y, equal to each other, represent an oxygen atom;
Z, equal to each other, represent a —O—R₄ group wherein R₄ represents a linear or branched C₁-C₃₀ alkyl group, preferably are a 2-octyldodecyloxy group;
A represents an electron-acceptor group or an electron-donor group wherein B represents a sulfur atom, Q₁ and Q₂, equal to each other, represent a C—R₁₂ group wherein R₁₂ is selected from C₁-C₂₀ alkyl groups, preferably is an octyl, R₉ and R₁₀, equal to each other, represent a fluorine atom; or represents an electron-acceptor group or an electron-donor group wherein B represents a sulfur atom and R₈ is selected from linear or branched C₁-C₂₀ alkyl groups, optionally halogenated, preferably is a trifluoroethyl.

For the purpose of the present description and of the following claims, the definitions of the numerical ranges always comprise the extreme values unless otherwise specified.

For the purpose of the present description and of the following claims, the term “comprising” also includes the terms “which essentially consists of” or “which consists of”.

For the purpose of the present description and of the following claims, the term “C₁-C₃₀ alkyl groups” and “C₁-C₂₀ alkyl groups” means alkyl groups having from 1 to 30 carbon atoms and from 1 to 20 carbon atoms, respectively, linear or branched, saturated or unsaturated. Specific examples of C₁-C₃₀ and C₁-C₂₀ alkyl groups are: methyl, ethyl, n-propyl, iso-propyl, n-butyl, iso-butyl, tert-butyl, pentyl, ethyl-hexyl, hexyl, heptyl, n-octyl, nonyl, decyl, dodecyl, 2-octyldodecyl, 2-ethyldodecyl, 2-butyloctyl, 2-hexyldecyl, 2-decyltetradecyl.

For the purpose of the present description and of the following claims, the term “optionally halogenated C₁-C₂₀ alkyl groups” means alkyl groups having from 1 to 20 carbon atoms, wherein at least one of the hydrogen atoms is substituted with a halogen atom such as, for example, fluorine, chlorine, preferably fluorine. Specific examples of optionally halogenated C₁-C₂₀alkyl groups are: fluoromethyl, difluoromethyl, trifluoromethyl, trifluoroethyl, trichloromethyl, 2,2,2-trifluoroethyl, 2,2,2-trichloroethyl, 2,2,3,3-tetrafluoropropyl, 2,2,3,3,3-pentafluoropropyl, perfluoropentyl, perfluorooctyl.

For the purpose of the present description and of the following claims, the term “cycloalkyl groups” means cycloalkyl groups having from 3 to 30 carbon atoms. Said cycloalkyl groups can optionally be substituted with one or more groups, equal or different from each other, selected from: halogen atoms such as, for example, fluorine, chlorine, bromine, preferably fluorine; hydroxyl groups; C₁-C₁₂ alkyl groups; C₁-C₁₂ alkoxyl groups; C₁-C₁₂ thioalkoxyl groups; C₃-C₂₄ tri-alkylsilyl groups; polyethyleneoxyl groups; cyano groups; amino groups; C₁-C₁₂ mono- or di-alkylamine groups; nitro groups. Specific examples of cycloalkyl groups are: cyclopropyl, 2,2-difluorocyclopropyl, cyclobutyl, cyclopentyl, cyclohexyl, methylcyclohexyl, methoxycyclohexyl, fluorocyclohexyl, phenylcyclohexyl, decalin, abietyl.

For the purpose of the present description and of the following claims, the term “aryl groups” means aromatic carbocyclic groups containing from 6 to 60 carbon atoms. Said aryl groups can optionally be substituted with one or more groups, equal to or different from each other, selected from: halogen atoms such as, for example, fluorine, chlorine, bromine, preferably fluorine; hydroxyl groups; C₁-C₁₂ alkyl groups; C₁-C₁₂ alkoxyl groups; C₁-C₁₂ thioalkoxyl groups; C₃-C₂₄ tri-alkylsilyl groups; polyethyleneoxyl groups; cyano groups; amino groups; C₁-C₁₂ mono- or di-alkylamine groups; nitro groups. Specific examples of aryl groups are: phenyl, methylphenyl, trimethylphenyl, methoxyphenyl, hydroxyphenyl, phenyloxyphenyl, fluorophenyl, pentafluorophenyl, chlorophenyl, bromophenyl, nitrophenyl, dimethylaminophenyl, naphthyl, phenylnaphtyl, phenanthrene, anthracene.

For the purpose of the present description and of the following claims, the term “heteroaryl groups” means heterocyclic aromatic, penta- or hexa-atomic groups, also benzocondensed or heterobicyclic, containing from 4 to 60 carbon atoms and from 1 to 4 heteroatoms selected from nitrogen, oxygen, sulfur, silicon, selenium, phosphorus. Said heteroaryl group can optionally be substituted with one or more groups, equal to or different from each other, selected from: halogen atoms such as, for example, fluorine, chlorine, bromine, preferably fluorine; hydroxyl groups; C₁-C₁₂ alkyl groups; C₁-C₁₂ alkoxyl groups; C₁-C₁₂ thioalkoxyl groups; C₃-C₂₄ tri-alkylsilyl groups; polyethyleneoxyl groups; cyano groups; amino groups; C₁-C₁₂ mono- or di-alkylamine groups; nitro groups. Specific examples of heteroaryl groups are: pyridine, methylpyridine, methoxypyridine, phenylpyridine, fluoropyridine, pyrimidine, pyridazine, pyrazine, triazine, tetrazine, quinoline, quinoxaline, quinazoline, furan, thiophene, hexylthiophene, bromothiophene, dibromothiophene, pyrrole, oxazole, thiazole, isoxazole, isothiazole, oxadiazole, tiadiazole, pyrazole, imidazole, triazole, tetrazole, indole, benzofuran, benzothiophene, benzooxazole, benzothiazole, benzooxadiazole, benzothiadiazole, benzopyrazole, benzimidazole, benzotriazole, triazolopyridine, triazolopirimidine, coumarin.

For the purpose of the present description and of the following claims, the term “C₁-C₂₀ alkoxyl groups” means groups comprising an oxygen atom to which a linear or branched, saturated or unsaturated C₁-C₂₀ alkoxyl groups is linked. Specific examples of C₁-C₂₀ alkoxyl groups are: methoxyl, ethoxyl, n-propoxyl, iso-propoxyl, n-butoxyl, iso-butoxyl, tert-butoxyl, pentoxyl, hexyloxyl, 2-ethylhexyloxyl, 2-hexyldecyloxyl, 2-octyltethradecyloxyl, 2-octyldodecyloxyl, 2-decyltetradecyloxyl, heptyloxyl, octyloxyl, nonyloxyl, decyloxyl, dodecyloxyl.

The term “C₁-C₂₀ alkylene groups” refers to alkylene groups having from 1 to 20 carbon atoms, linear or branched. Specific examples of C₁-C₂₀ alkylene groups are: methylene, ethylene, n-propylene, iso-propylene, n-butylene, iso-butylene, tert-butylene, pentylene, ethyl-hexylene, hexylene, heptylene, octylene, nonylene, decylene, dodecylene.

The term “polyethylenoxyl groups” means a group having oxyethylene units in the molecule. Specific examples of polyethylenoxyl group are: methyloxy-ethylenoxyl, methyloxy-diethyleneoxyl, 3-oxatetraoxyl, 3,6-dioxaheptyloxyl, 3,6,9-trioxadecyloxyl, 3,6,9,12-tetraxohexadecyloxyl.

The conjugated anthradithiophene terpolymers having general formula (I) can be obtained by processes known in the art.

For example, the conjugated anthradithiophene terpolymer having general formula (I) may be obtained by a process comprising reacting at least one anthradithiophene derivative having general formula (II):

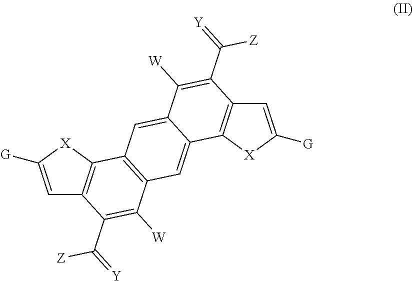

wherein X, Y, W and Z, have the same meanings reported above, G is selected from groups —Sn(Rₐ)₃ wherein Rₐ, equal or different from each other, are selected from linear or branched C₁-C₂₀ alkyl groups; or from —B(OR′)₃ groups, wherein B is boron and R′, equal or different from each other, represent a hydrogen atom, or are selected from linear or branched C₁-C₂₀ alkyl groups; or the OR′ groups together with the other atoms to which they are bonded, can form a heterocyclic ring having the following formula:

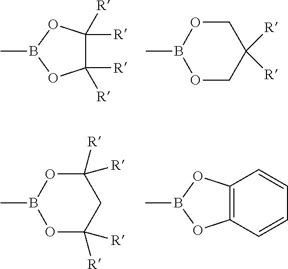

wherein the substituents R′, equal or different from each other, represent a hydrogen atom, or are selected from linear or branched C₁-C₂₀ alkyl groups and B is boron, with at least one compound having general formula (III):

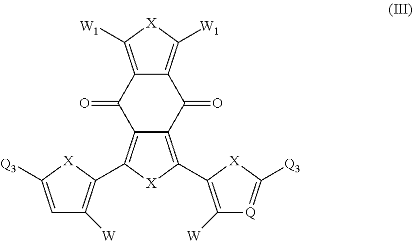

wherein Q₃ represents a halogen atom selected from chlorine, bromine, iodine, preferably bromine and X, Q, W and W₁ have the same meanings reported above, and with at least one compound having general formula (IV):

Q₃-A-Q₃ (IV)

wherein Q₃ and A have the same meanings reported above.

Said process can be carried out according to techniques known in the art as described, for example, by Wu M. et al. in the article “Additive-free non-fullerene organic solar cells with random copolymers as donors over 9% power conversion efficiency”, “Chinese Chemical Letters” (2019), Vol. 30, pages 1161-1167: further details can be found in the following examples.

Said anthradithiophene derivative (II) may be obtained according to processes known in the art as described, for example, in international patent application WO 2019/175367 in the name of the Applicant reported above.

Said compound having general formula (III) can be obtained according to processes known in the art as reported, for example, by Zheng B. et al. in the article “Benzodithiophenedione-based polymers: recent advances in organic photovoltaics”, “NPG Asian Materials” (2020), Vol. 12, pages 3-25.

Said compound having general formula (IV) can be obtained according to processes known in the art as reported, for example, by Liu Y. et al. in the article “Aggregation and morphology control enables multiple cases of high-efficiency polymer solar cells”, “Nature Communication” (2014), Vol. 5, pages 1-8; Yao C. et al., in the article “Fluorinate a Polymer Donor through Trifluoromethyl Group for High-Performance Polymer Solar Cells”, “Journal of Materials Chemistry A” (2020), Vol. 8, pages 12149-12155.

As said above, said conjugated anthradithiophene terpolymer having general formula (I) can be advantageously used in the construction of photovoltaic devices (or solar devices) such as, for example, photovoltaic cells (or solar cells), photovoltaic modules (or solar modules), either on a rigid support, or on a flexible support.

The present disclosure further provides a photovoltaic device (or solar device) such as, for example, a photovoltaic cell (or solar cell), a photovoltaic module (or solar module), either on a rigid support, or on a flexible support, comprising at least one conjugated anthradithiophene terpolymer having general formula (I).

For the purpose of the present disclosure, the organic electron-acceptor compound can be selected, for example, from derivatives of fullerene such as, for example, methyl ester of the [6,6]-phenyl-C₆₁-butyric acid (PC61BM), methyl ester of the (6,6)-phenyl-C₇₁-butyric acid (PC71BM), bis-adduct indene-C₆₀ (ICBA), bis(1-[3-(methoxycarbonyl)propyl]-1-phenyl)-[6.6]C62 (Bis-PCBM). Methyl ester of the [6,6]-phenyl-C₆₁-butyric acid (PC61BM), methyl ester of the (6,6)-phenyl-C₇₁-butyric acid (PC71BM), are preferred.

Alternatively, said organic electron-acceptor compound can be selected, for example, among non-fullerenic, optionally polymeric, compounds, such as, for example, compounds based on perylene-diimides or naphthalene-diimides and fused aromatic rings; indacenotiophenes with electron-poor terminal groups; compounds having an aromatic core capable of symmetrically rotating, for example, derivatives of corannulene or truxenone. 3,9-Bis(2-methylene-[3-(1,1-dicyanomethylene)-6,7-difluoro)-indanone))-5,5,11,11-tetrakis(4-hexylphenyl)-dithieno[2,3-d:2′,3′-d′]-s-indacene-[1,2-b:5,6-b′]-dithiophene, poly{[N,N′-bis(2-octyldodecyl)-1,4,5,8-naphthalene-diimide-2,6-diyl]-alt-5,5′-(2,2′-bithiophene)}, 2,2′-((2Z,2′Z)-((4,4,9,9-tetrahexyl-4,9-dihydro-s-indacene[1,2-b:5,6-b′]dithiophene-2,7-diyl)bis(methanylylidene))bis(3-oxo-2,3-dihydro-1H-indene-2,1-diylidene))dimalononitrile, are preferred.

More details relating to said non-fullerenic compounds can be found, for example, in Nielsen C. B. et al., “Accounts of Chemical Research” (2015), Vol. 48, pages 2803-2812; Zhan C. et al., “RSC Advances” (2015), Vol. 5, pages 93002-93026.

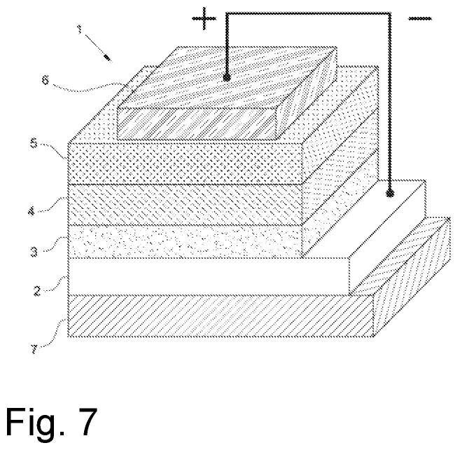

FIG. 7 below shows a cross sectional view of an inverted polymer photovoltaic cell (or solar cell) used in Examples 8-12 given below.

With reference to FIG. 7, the inverted polymer photovoltaic cell (or solar cell) (1) comprises:
a transparent glass support (7);
a cathode (2) of indium-tin oxide (ITO);
a cathodic buffer layer (3) comprising zinc oxide (ZnO);
a layer of photoactive material (4) comprising regioregular poly(3-hexylthiophene) (P3HT) or an anthradithiophene conjugated terpolymer having general formula (I) and the methyl ester of the [6,6]-phenyl-C₆₁-butyric acid (PC₆₁BM), or 3,9-bis(2-methylene-((3-(1,1-dicyanomethylene)-6,7-difluoro)-indanone))-5,5,11,11-tetrakis(4-hexyl-phenyl)-dithieno[2,3-d:2′,3′-d′]-s- indacene[1,2-b:5,6-b′]dithiophene (IT-4F), or 2,2′-((2Z,2′Z)-((4,4,9,9-tetrahexyl-4,9-dihydro-s-indacene[1,2-b:5,6-b′]dithiophene-2,7-diyl)bis(methanylidene))bis(3-oxo-2,3-dihydro-1H-indene-2,1-diylidene))dimalononitrile (IDIC);
an anodic buffer layer (5) comprising molybdenum oxide (MoO₃);
a silver (Ag) anode (6).

### DETAILED DESCRIPTION

In order to better understand the present disclosure and to put it into practice, some illustrative and non-limiting examples thereof are reported below.

### EXAMPLES

### Characterisation of the Terpolymers Obtained

### Determination of the Molecular Weight

The molecular weight of the terpolymers obtained by operating in accordance with the following examples, was determined by “Gel Permeation Chromatography” (GPC) on a WATERS 150 C instrument, using HT5432 columns, with trichlorobenzene eluent, at 80° C.

The weight average molecular weight (M_{w}), the number average molecular weight (Mₙ) and the polydispersity index (“PDI”), corresponding to the M_{w}/Mₙ ratio, are given.

### Determination of the Optical “Band-Gap”

The terpolymers obtained by operating in accordance with the following examples, were characterized by UV-Vis-NIR spectroscopy to determine the energetic entity of the optical “band-gap” in solution or on thin film according to the following procedure.

In the case that the “optical band-gap” was measured in solution, the terpolymer was dissolved in toluene, chloroform, chlorobenzene, dichlorobenzene, trichlorobenzene, or other suitable solvent. The solution thus obtained was placed in a quartz cuvette and analysed in transmission by means of a double-beam UV-Vis-NIR spectrophotometer and double monochromator Perkin Elmer λ950, in the range 200 nm-850 nm, with a 2.0 nm bandwidth, scanning speed of 220 nm/min and 1 nm step, using as a reference an identical quartz cuvette containing only the solvent used as a reference.

In the case that the “optical band-gap” was measured on thin film, the terpolymer was dissolved in toluene, chloroform, chlorobenzene, dichlorobenzene, trichlorobenzene, or other suitable solvent, obtaining a solution having a concentration equal to about 10 mg/ml, which was deposited by spin-coating on a Suprasil quartz slide. The thin film thus obtained was analysed in transmission by means of a dual-beam UV-Vis-NIR spectrophotometer and double monochromator Perkin Elmer λ950, in the range 200 nm-850 nm, with a 2.0 nm bandwidth, scanning speed of 220 nm/min and 1 nm step, using an identical Suprasil quartz slide as such, as a reference.

The optical “band-gap” was estimated from the spectra in transmission by measuring the absorption edge corresponding to the transition from the valence band (VB) to the conduction band (CB). The intersection with the abscissa axis of the straight line tangent to the absorption band at the inflection point was used for the determination of the edge.

The inflection point (λ_{F}, y_{F}) was determined on the basis of the coordinates of the minimum of the spectrum in the first derivative, indicated with λ′ₘᵢₙ and y′ₘᵢₙ.

The equation of the straight line tangent to the UV-Vis spectrum at the inflection point (λ_{F}, y_{F}) is as follows:

y=y′ₘᵢₙλ+y_{F}−y′ₘᵢₙλ′ₘᵢₙ

Finally, from the condition of intersection with the abscissa axis ψ=0, it was obtained:

λ_{EDGE}=(y′ₘᵢₙλ′ₘᵢₙ−y_{F})/y′ₘᵢₙ

Therefore, by measuring the coordinates of the minimum of the first derivative spectrum and the corresponding absorbance value y_{F} from the UV-Vis spectrum, λ_{EDGE} was obtained directly by substitution.

The corresponding energy is:

E_{EDGE}=hν_{EDGE}=hc/λ_{EDGE}

wherein:
h=6.626 10−34 Js;
c=2.998 108 ms⁻¹;
   that is:

E_{EDGE}=1.98810−16J/λ_{EDGE}(nm).

Lastly, remembering that 1 J=6.24 1018 eV, we have:

E_{EDGE}=1240eV/λ_{EDGE}(nm).

### Determination of HOMO and LUMO

The determination of the HOMO and LUMO values of the terpolymers obtained by operating in accordance with the following examples, was carried out using the cyclic voltammetry (CV) technique. This technique makes it possible to measure the values of the potentials of formation of the radical cation and radical anion of the sample under examination. These values, inserted in a special equation, allow the HOMO and LUMO values of the terpolymer in question to be obtained. The difference between HOMO and LUMO makes the value of the electrochemical “band-gap”.

The values of the electrochemical “band-gap” are generally higher than the values of the optical “band-gap” since during the execution of the cyclic voltammetry (CV), the neutral compound is charged and undergoes a conformational reorganization, with an increase in the energy gap, while optical measurement does not lead to the formation of charged species.

The cyclic voltammetry (CV) measurements were performed with an Autolab PGSTAT12 potentiostat (with GPES Ecochemie software) in a three-electrode cell. In the measurements carried out, an Ag/AgCl electrode was used as the reference electrode, a platinum wire as the counter electrode and a glassy graphite electrode as the working electrode. The sample to be analysed was dissolved in a suitable solvent and subsequently deposited, with a calibrated capillary, on the working electrode, so as to form a film. The electrodes were immersed in a 0.1 M electrolytic solution of 95% tetrabutylammonium tetrafluroborate in acetonitrile. The sample was subsequently subjected to a cyclic potential in the shape of a triangular wave. At the same time, as a function of the applied potential difference, the current, which signals the occurrence of oxidation or reduction reactions of the present species, was monitored.

The oxidation process corresponds to the removal of an electron from HOMO, while the reduction cycle corresponds to the introduction of an electron into LUMO. The potentials of formation of radical cation and radical anion were derived from the value of the peak onset (Eₒₙₛₑₜ), which is caused by molecules and/or chain segments with HOMO-LUMO levels closer to the edges of the bands. The electrochemical potentials to those related to the electronic levels can be correlated if both refer to the vacuum. For this purpose, the potential of ferrocene in vacuum, known in the literature and equal to −4.8 eV, was taken as a reference. The inter-solvent redox pair ferrocene/ferrocinium (Fc/Fc⁺) was selected because it has an oxide-reduction potential independent of the working solvent.

The general formula for calculating the energies of the HOMO-LUMO levels is therefore given by the following equation:

E(eV)=−4,8+[E_{1/2Ag/AgCl}(Fc/Fc⁺)−E_{onsetAg/AgCl}(terpolymer)]

wherein:
E=HOMO or LUMO according to the entered Eₒₙₛₑₜ value;
E_{1/2Ag/AgCl}=half-wave potential of the peak corresponding to the redox pair ferrocene/ferrocinium measured under the same analysis conditions as the sample and with the same triad of electrodes used for the sample;
E_{onsetAg/AgCl}=onset potential measured for the terpolymer in the anodic area when calculating HOMO and in the cathodic area when calculating LUMO.

### Example 1

### Preparation of 2,5-dibromothiophene-3-carboxylic Acid Having Formula (V)

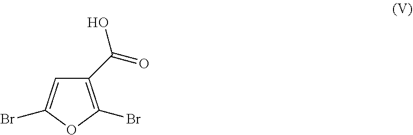

In a 100 ml flask, fitted with magnetic stirrer, thermometer and refrigerant, in an inert atmosphere, to a solution of 3-thiophenecarboxylic acid (Merck) (4 g; 31 mmol) in N,N-dimethylformamide (DMF) (Merck) (40 ml), at 60° C., it was added N-bromosuccinimide (Merck) (11.57 g; 65 mmol), in small portions, over 15 minutes: the resulting reaction mixture was left, in an inert atmosphere, under stirring, at 60° C., for 24 hours. Subsequently, the reaction mixture was placed in deionised water and ice and the white precipitate obtained was recovered by filtration obtaining a solid. The solid product obtained was dried in a vacuum oven, at 55° C., for 4 hours, obtaining 7.53 g of 2,5-dibromothiophene-3-carboxylic acid having formula (V) (yield 85%).

### Example 2

### Preparation of 2,2,2-trifluoroethyl-2,5-dibromothiophene-3-carboxylate Having Formula (VI)

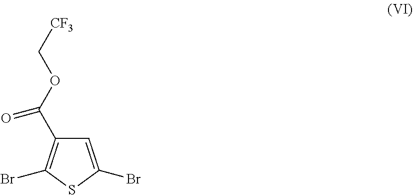 [SMILES: O=C(OCC(F)(F)F)c1cc(Br)sc1Br]

In a 100 ml flask, fitted with magnetic stirrer, thermometer and refrigerant, in an inert atmosphere, to a solution of 2,5-dibromothiophene-3-carboxylic acid having formula (V) obtained as described in Example 1 (1.43 g; 5 mmol) in dichloromethane (DCM) (Merck) (50 ml), at room temperature (25° C.), it was added, N,N′-dicyclohexylcarbodiimide (DCC) (Merck) (1.032 g; 5 mmol), 4-(N,N-dimethylamino)pyridine (DMAP) (Merck) (0.357 g; 1.25 mmol) and 2,2,2-trifluoroethanol (Merck) (0.502 g; 5 mmol): the resulting reaction mixture was left, in an inert atmosphere, under stirring, at room temperature (25° C.), for 24 hours. Subsequently, the reaction mixture was placed in a 500 ml separating funnel: deionised water (3×100 ml) was added to said reaction mixture and the whole was extracted with dichloromethane (Merck) (3×100 ml) obtaining an aqueous phase and an organic phase. The entire organic phase (obtained by combining the organic phases deriving from the three extractions) was separated and subsequently dried over anhydrous sodium sulphate (Merck) and evaporated. The residue obtained was purified by elution on a chromatographic column of silica gel [(eluent: n-heptane/dichloromethane 9/1) (Merck)], obtaining 1.656 g of 2,2,2-trifluoroethyl-2,5-dibromothiophene-3-carboxylate having formula (VI) as a white solid (90% yield).

### Example 3

### Preparation of 2,5-dibromobenzene-1,4-dicarbaldehyde Having Formula (VII)

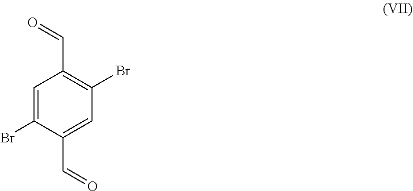 [SMILES: O=Cc1cc(Br)c(C=O)cc1Br]

In a 100 ml flask, fitted with magnetic stirring, thermometer and coolant, in an inert atmosphere, to a solution of terephthaldehyde (Aldrich) (4.02 g; 30 mmoles) in sulfuric acid (Aldrich) (40 ml) it was added N-bromosuccinaldehyde (Aldrich) (11.57 g; 65 mmoles) in small portions, over 15 minutes: the reaction mixture obtained was left, in an inert atmosphere, under stirring, at room temperature (25° C.), for 3 hours. Subsequently, the reaction mixture was placed in water and ice and the white precipitate obtained was recovered by filtration obtaining a solid. The solid was dissolved in dichloromethane (Aldrich) (200 ml) and the solution obtained was placed in a 500 ml separating funnel: the whole was extracted with a saturated sodium bicarbonate solution (Aldrich) (3×100 ml) obtaining an acidic aqueous phase and an organic phase. The entire organic phase (obtained by combining the organic phases deriving from the three extractions) was washed to neutral with distilled water (3×50 ml) and subsequently anhydrified on sodium sulphate (Aldrich) and evaporated obtaining a solid which was further purified by crystallization with ethyl acetate (Aldrich). The crystals obtained were collected by filtration obtaining 6.57 g of 2,5-dibromobenzene-1,4-dicarbaldehyde having formula (VII) (yield 75%).

### Example 4

### Preparation of bis(2-octyldodecyl)anthra[1,2-b:5,6-b′]dithiophene-4,10-dicarboxylate Having Formula (VIII)

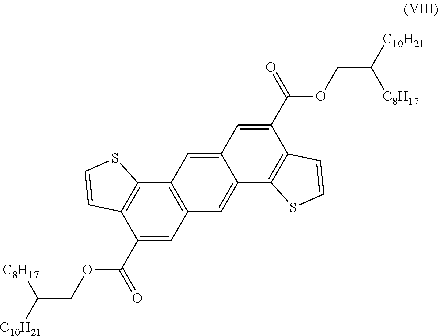

In a 100 ml flask, fitted with magnetic stirrer, thermometer and refrigerant, in an inert atmosphere, to a mixture of 3-thiopheneacetic acid (Aldrich) (0.312 g; 2 mmol), triphenylphosphine (Aldrich) (0.026 g; 0.1 mmol), palladium(II)acetate Pd(OAc)₂ (Aldrich) (0.112 g; 0.5 mmol) in N,N-dimethylformamide anhydrous (DMF) (Aldrich) (5 ml), it was added 2,5-dibromobenzene-1,4-dicarbaldehyde having formula (VII) obtained as described in Example 3 (0.292 g; 1 mmol) and potassium carbonate (K₂CO₃) (Aldrich) (0.691 g; 5 mmol): the resulting mixture was heated at 80° C. and kept under stirring, at said temperature, for 24 hours. Subsequently, 1-bromo-2-octyldodecane (Sunatech) (0.795 g; 2.2 mmol) was added in a single portion: the reaction mixture obtained was left, under stirring, at 80° C., for 24 hours. Subsequently, after cooling to room temperature (25° C.), the reaction mixture was placed in a 500 ml separating funnel: an ammonium chloride (NH₄Cl) 0.1 (Aldrich) (3×100 ml) solution was added to said reaction mixture and the whole was extracted with ethyl acetate (Aldrich) (3×100 ml) obtaining an aqueous phase and an organic phase. The entire organic phase (obtained by combining the organic phases deriving from the three extractions) was separated and subsequently anhydrified on sodium sulphate (Aldrich) and evaporated. The residue obtained was purified by elution on a chromatographic column of silica gel [(eluent: n-heptane/ethyl acetate 98/2) (Carlo Erba)], obtaining 0.752 g of bis(2-octyldodecyl)anthra[1,2-b:5,6-b′]dithiophene-4,10-dicarboxylate having formula (VIII) as a waxy yellow solid (yield 80%).

### Example 5

### Preparation of bis(2-octyldodecyl)-2,7-bis-(tributylstannyl)anthra[1,2-b:5,6-b′]dithiophene-4,10-dicarboxylate Having Formula (IIa)

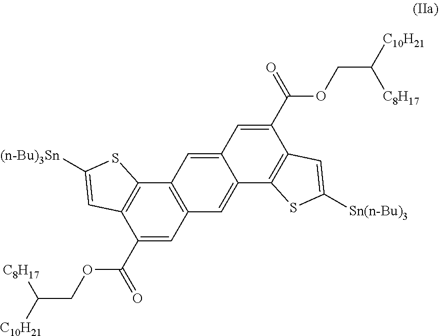

In a 250 ml flask, fitted with magnetic stirring, it was loaded, under argon flow, in this order: bis(2-octyldodecyl)anthra[1,2-b:5,6-b′]dithiophene-4,10-dicarboxylate having formula (VIII) obtained as described in Example 4 (0.47 g; 0.5 mmol) and 40 ml of anhydrous tetrahydrofuran (THF) (Aldrich): the reaction mixture obtained was placed, at −78° C., for about 10 minutes. Subsequently, 4.4 ml of a solution of lithium di-iso-propylamine(LDA) (Aldrich) were added by dripping in a mixture of tetrahydrofuran (THF) (Aldrich)/hexane (Aldrich) (1:1, v/v) 2.0 M (0.182 g; 1.7 mmoles): the reaction mixture obtained was maintained, at −78° C., for 3 hours. Subsequently, 0.678 ml of tri-butyl tin chloride (Aldrich) (1.302 g; 4 mmoles) were added by dripping: the reaction mixture obtained was placed at −78° C., for 30 minutes and, subsequently, at room temperature (25° C.), for 16 hours. Subsequently, the reaction mixture was placed in a 500 ml separating funnel: said reaction mixture was diluted with a 0.1 M sodium bicarbonate solution (Aldrich) (200 ml) and extracted with diethyl ether (Aldrich) (3×100 ml), obtaining an acid aqueous phase and an organic phase. The entire organic phase (obtained by combining the organic phases deriving from the three extractions) was washed to neutral with water (3×50 ml) and subsequently anhydrified on sodium sulphate (Aldrich) and evaporated. The residue obtained was purified by elution on a basic alumina chromatographic column (Aldrich) [(eluent: n-heptane) (Aldrich)], obtaining 0.607 g of bis(2-octyldodecyl)-2,7-bis-(tributylstannyl)-anthra[1,2-b:5,6-b′]dithiophene-4,10-dicarboxylate having formula (IIa) as straw yellow oil (yield 80%).

### Example 6

### Preparation of Conjugated Anthradithiophene Terpolymer Having Formula (Ia)

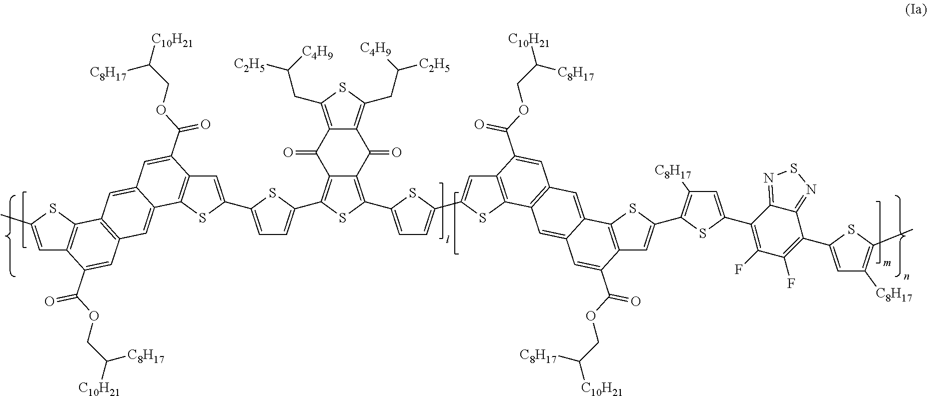

In a 250 ml flask, fitted with magnetic stirring, thermometer and coolant, in an inert atmosphere, it was loaded in this order: bis(2-octyldodecyl)-2,7-bis(tributylstannyl)anthra[1,2-b:5,6-b′]dithiophene-4,10-dicarboxylate having formula (IIa) obtained as described in Example 5 (1.517 g; 1.05 mmol), 100 ml of chlorobenzene (Aldrich), 1,3-bis(5-bromothiophen-2-yl)-5,7-bis(2-ethylhexyl)benzo[1,2-c:4,5-c′]dithiophene-4,8-dione (Sunatech) (0.690 g; 0.90 mmoles), 4,7-bis(5-bromo-4-octylthiophene-2-yl)-5,6-difluorobenzo[c][1,2,5]thiadiazole (Sunatech) (0.072 g; 0.1 mmoles), tris(dibenzylideneacetone)dipalladium(0) [Pd₂(dba)₃] (Aldrich) (0.018 g; 0.02 mmol) and tris(ortho-tolyl)phosphine [P(o-tol)₃] (Aldrich) (0.024 g; 0.08 mmol). Subsequently, the reaction mixture obtained was heated to reflux and kept under stirring for 18 hours: the colour of the reaction mixture turned purple after 3 hours and turned dark purple at the end of the reaction (i.e. after 18 hours). Subsequently, after cooling to room temperature (25° C.), the reaction mixture obtained was placed in methanol (Aldrich) (300 ml) and the precipitate obtained was subjected to sequential extraction in a Soxhlet apparatus with methanol (Aldrich), acetone (Aldrich), n-heptane (Aldrich), dichloromethane (Aldrich), finally, chloroform (Aldrich). The residue left inside the extractor was dissolved in chlorobenzene (50 ml) (Aldrich) at 80° C. The hot solution was precipitated in methanol (300 ml) (Aldrich). The obtained precipitate was collected and dried under vacuum at 50° C., for 16 hours, obtaining 1.4 g of a dark violet solid product (90% yield), corresponding to the conjugated anthradithiophenic terpolymer having formula (Ia).

Said solid product was subjected to determination of the molecular weight by “Gel Permeation Chromatography” (GPC) operating as described above, obtaining the following data:
(M_{w})=38574 Dalton;
(PDI)=2.0334.

The values of the optical “band-gap”, operating as described above, both in solution (E_{g}^{opt}ₛₒₗᵤₜᵢₒₙ), and on thin film (E_{g}^{opt}_{film}) and the HOMO value were also determined:
(λ_{EDGE} sol)=651 nm;
(λ_{EDGE} film)=654 nm;
E_{g.opt.sol}=1.95 eV;
E_{g.opt.film}=1.91 eV;
(HOMO)=−5.30 eV.

### Example 7

### Preparation of a Conjugated Anthradithiophene Terpolymer Having Formula (Ib)

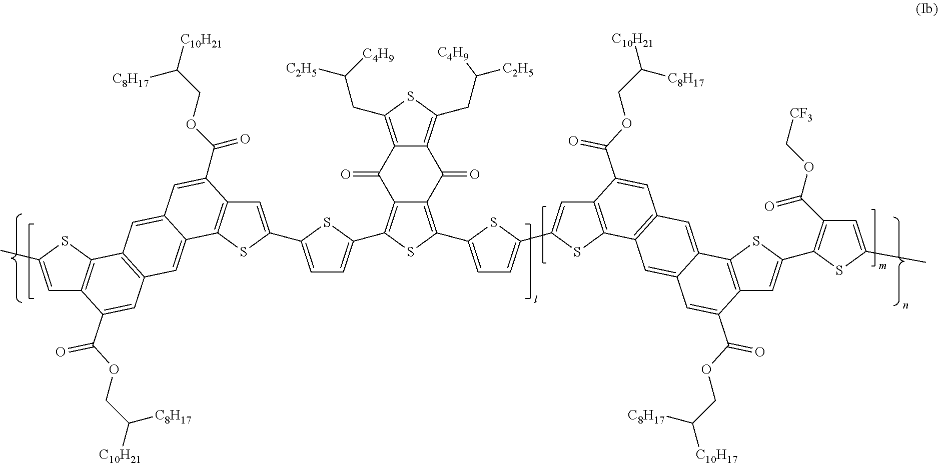

In a 250 ml flask, fitted with magnetic stirring, thermometer and coolant, in an inert atmosphere, it was loaded in this order: bis(2-octyldodecyl)-2,7-bis(tributylstannyl)anthra[1,2-b:5,6-b′]dithiophene-4,10-dicarboxylate having formula (IIa) obtained as described in Example 5 (1.517 g; 1.05 mmol), 100 ml of chlorobenzene (Aldrich), 1,3-bis(5-bromothiophen-2-yl)-5,7-bis(2-ethylhexyl)benzo[1,2-c:4,5-c′]dithiophene-4,8-dione (Sunatech) (0.69 g; 0.9 mmoles), 2,2,2-trifluoroethyl-2,5-dibromothiophene-3-carboxylate having formula (VI) obtained as described in Example 2 (0.368 g; 0.1 mmol), tris(dibenzylideneacetone)dipalladium(0) [Pd₂(dba)₃] (Aldrich) (0.018 g; 0.02 mmoles) and tris(ortho-tolyl)phosphine [P(o-tol)₃] (Aldrich) (0.024 g; 0.08 mmoles). Subsequently, the reaction mixture obtained was heated to reflux and kept, under stirring, for 18 hours: the colour of the reaction mixture turned purple after 3 hours and turned dark purple at the end of the reaction (i.e. after 18 hours). Subsequently, after cooling to room temperature (25° C.), the reaction mixture obtained was placed in methanol (Aldrich) (300 ml) and the precipitate obtained was subjected to sequential extraction in a Soxhlet apparatus with methanol (Aldrich), acetone (Aldrich), n-heptane (Aldrich), dichloromethane (Aldrich), finally, chloroform (Aldrich). The residue left inside the extractor was dissolved in chlorobenzene (50 ml) (Aldrich) at 80° C. The hot solution was precipitated in methanol (300 ml) (Aldrich). The obtained precipitate was collected and dried under vacuum at 50° C. for 16 hours, obtaining 1.384 g of a dark violet solid product (92% yield), corresponding to the conjugated anthradithiophenic terpolymer having formula (Ib).

Said solid product was subjected to determination of the molecular weight by “Gel Permeation Chromatography” (GPC) operating as described above, obtaining the following data:
(M_{w})=45796 Dalton;
(PDI)=1.8472.

The values of the optical “band-gap”, operating as described above, both in solution (E_{g}^{opt}ₛₒₗᵤₜᵢₒₙ), and on thin film (E_{g}^{opt}_{film}) and the HOMO value were also determined:
(λ_{EDGE} sol)=646 nm;
(λ_{EDGE} film)=660 nm;
E_{g.opt.sol}=1.92 eV;
E_{g.opt.film}=1.88 eV;
(HOMO)=−5.45 eV.

### Example 8 (Comparative)

### Solar Cell Comprising Regioregular poly-3-hexylthiophene (P3HT)

For this purpose, an inverted polymer solar cell was used, schematically represented in FIG. 7.

For this purpose, a polymer-based device was prepared on an ITO (indium-tin oxide) coated glass substrate (Kintec Company—Hong Kong), previously subjected to a cleaning procedure comprising a manual cleaning, rubbing with a lint-free cloth soaked in a detergent diluted with tap water. The substrate was then rinsed with tap water. Subsequently, the substrate was thoroughly cleaned using the following methods in sequence: ultrasonic baths in (i) distilled water plus detergent (followed by manual drying with a lint-free cloth); (ii) distilled water [followed by manual drying with a lint-free cloth]; (iii) acetone (Aldrich) and (iv) iso-propanol (Aldrich) in sequence. In particular, the substrate was placed in a beaker containing the solvent, placed in an ultrasonic bath, kept at 40° C., for a treatment of 10 minutes. After treatments (iii) and (iv), the substrate was dried with a compressed nitrogen flow.

Subsequently, the glass/ITO was further cleaned in an air plasma device (Tucano type—Gambetti), immediately before proceeding to the next step.

The substrate thus treated was ready for the deposition of the cathodic buffer layer. For this purpose, the zinc oxide (ZnO) buffer layer was obtained starting from a 0.162 M solution of the complex [Zn²⁺]-ethanolamine (Aldrich) in butanol (Aldrich). The solution was deposited by rotation on the substrate operating at a rotation speed equal to 600 rpm (acceleration equal to 300 rpm/s), for 2 minutes and 30 seconds, and subsequently at a rotation speed equal to 1500 rpm, for 5 seconds. Immediately after deposition of the cathodic buffer layer, zinc oxide formation was obtained by thermally treating the device at 140° C., for 5 minutes, on a hot plate in ambient air. The cathodic buffer layer thus obtained had a thickness equal to 30 nm and was partially removed from the surface with 0.1 M acetic acid (Aldrich), leaving the layer only on the desired surface.

The active layer, comprising regioregular poly-3-hexylthiophene (P3HT) (Plexcore OS) and methyl ester of the [6,6]-phenyl-C₆₁-butyric acid (PC61BM) (Aldrich), was deposited on the cathodic buffer layer thus obtained by “spin coating” of a 1:0.8 (v/v) solution in o-dichlorobenzene (Aldrich) with a P3HT concentration equal to 10 mg/ml which had been kept under stirring overnight, operating at a rotation speed of 300 rpm (acceleration equal to 255 rpm/s), for 90 seconds. The thickness of the active layer was found to be 250 nm.

On the active layer thus obtained, the anodic buffer layer was deposited, which was obtained by depositing molybdenum oxide (MoO₃) (Aldrich) through a thermal process: the thickness of the anodic buffer layer was equal to 10 nm. A silver (Ag) anode, having a thickness equal to 100 nm, was deposited on the anodic buffer layer by vacuum evaporation, appropriately masking the area of the device in order to obtain an active area equal to 25 mm².

The depositions of the anodic buffer layer and of the anode were carried out in a standard evaporation chamber under vacuum containing the substrate and two evaporation vessels equipped with a heating resistance containing 10 mg of molybdenum oxide (MoO₃) in powder and 10 (Ag) silver shots (diameter 1 mm-3 mm) (Aldrich), respectively. The evaporation process was carried out under vacuum, at a pressure of about 1×10⁻⁶ bar. The molybdenum oxide (MoO₃) and silver (Ag), after evaporation, are condensed in the unmasked parts of the device.

The thicknesses were measured with a Dektak 150 (Veeco Instruments Inc.) profilometer.

The electrical characterization of the device obtained was carried out in a controlled atmosphere (nitrogen) in a “glove box”, at room temperature (25° C.). The current-voltage curves (I-V) were acquired with a Keithley® 2600A multimeter connected to a personal computer for data collection. The photocurrent was measured by exposing the device to the light of an ABET SUN® 2000-4 solar simulator, capable of providing 1.5G AM radiation with an intensity equal to 100 mW/cm² (1 sun), measured with an Ophir Nova® II “powermeter” connected to a 3A-P thermal sensor. The device, in particular, is masked before said electrical characterization, so as to obtain an effective active area equal to 16 mm²: Table 2 shows the four characteristic parameters as average values.

### Example 9 (Disclosure)

### Solar Cell Disclosure Comprising the Conjugated Anthradithiophene Terpolymer Having Formula (Ia)

A polymer-based device was prepared on an ITO (indium-tin oxide) coated glass substrate (Kintec Company—Hong Kong), previously subjected to a cleaning procedure operating as described in Example 8.

The deposition of the cathodic buffer layer and the deposition of the anodic buffer layer were carried out as described in Example 8; the composition of said cathodic buffer layer and the composition of said anodic buffer layer are the same as the ones in Example 8; the thickness of said cathodic buffer layer and the thickness of said anodic buffer layer are the same as the ones in Example 8.

The active layer, comprising the conjugated anthradithiophene terpolymer having formula (Ia) obtained as described in Example 6 and the methyl ester of [6.6]-phenyl-C₆₁-butyric acid (PC61BM) (Aldrich), was deposited on the cathodic buffer layer thus obtained by spin coating of a 1/1 (v/v) solution in o-xylene (Aldrich) with a concentration of conjugated anthradithiophene terpolymer having formula (Ia) equal to 10 mg/ml which had been kept at 100° C. under stirring overnight, operating at a rotation speed equal to 2000 rpm (acceleration equal to 2500 rpm/s), for 30 seconds. The thickness of the active layer was found to be 102 nm.

The deposition of the silver (Ag) anode was carried out as described in Example 8: the thickness of said silver anode (Ag) is the same as the one reported in Example 8.

The thicknesses were measured with a Dektak 150 (Veeco Instruments Inc.) profilometer.

The electrical characterization of the obtained device was carried out as described in Example 8: Table 2 shows the four characteristic parameters as average values.

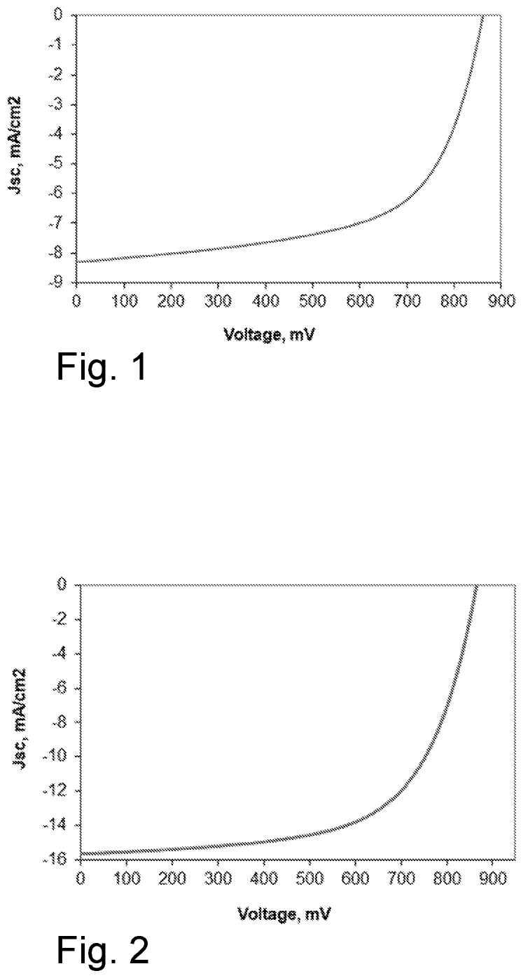

FIG. 1 shows the current-voltage curve (I-V) obtained [the abscissa shows the voltage in millivolts (mV); the ordinate shows the short-circuit current density (Jsc) in milliampere/cm² (mA/cm²)].

### Example 10 (Disclosure)

### Solar Cell Comprising the Conjugated Anthradithiophene Terpolymer of Formula (Ia)

A polymer-based device was prepared on an ITO (indium-tin oxide) coated glass substrate (Kintec Company—Hong Kong), previously subjected to a cleaning procedure operating as described in Example 8.

The deposition of the cathodic buffer layer and the deposition of the anodic buffer layer were carried out as described in Example 8; the composition of said cathodic buffer layer and the composition of said anodic buffer layer are the same as the ones in Example 8; the thickness of said cathodic buffer layer and the thickness of said anodic buffer layer are the same as the ones in Example 8.

The active layer, comprising the conjugated anthradithiophene terpolymer having formula (Ia) obtained as described in Example 6 and 3,9-bis(2-methylene-((3-(1,1-dicyanomethylene)-6,7-difluoro)-indanone))-5,5,11,11-tetrakis(4-hexyl-phenyl)-dithiene[2,3-d:2′,3′-d′]-s-indacene[1,2-b:5,6-b′]dithiophene (IT-4F) (Ossila), was deposited on the cathodic buffer layer thus obtained by spin coating of a 1:1 (v:v) solution in o-dichlorobenzene (Aldrich) with a concentration of anthradithiophenic conjugated terpolymer having formula (Ia) equal to 10 mg/ml which had been kept under stirring at 100° C. overnight, operating at a rotation speed equal to 2000 rpm (acceleration equal to 2500 rpm/s), for 30 seconds. The thickness of the active layer was found to be 102 nm.

The deposition of the silver (Ag) anode was carried out as described in Example 8: the thickness of said silver anode (Ag) is the same as the one reported in Example 8.

The thicknesses were measured with a Dektak 150 (Veeco Instruments Inc.) profilometer.

The electrical characterization of the obtained device was carried out as described in Example 8: Table 2 shows the four characteristic parameters as average values.

FIG. 2 shows the current-voltage curve (I-V) obtained [the abscissa shows the voltage in millivolts (mV); the ordinate shows the short-circuit current density (Jsc) in milliampere/cm² (mA/cm²)].

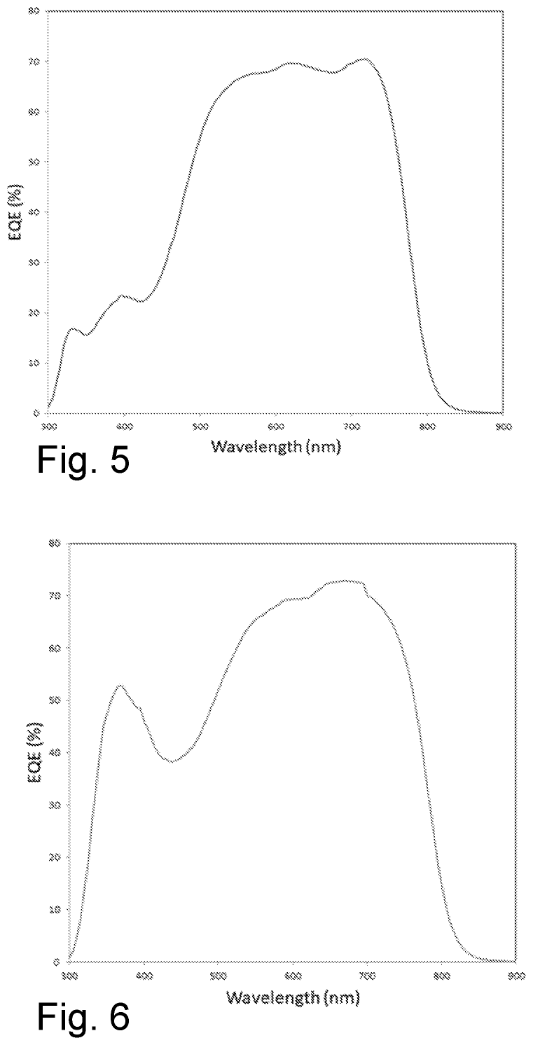

FIG. 5 shows the curve relating to the External Quantum Efficiency (EQE) which was recorded under a monochromatic light (obtained using the TMc300F-U (I/C)—“Triple grating monochromator” and a double source with a Xenon lamp and a halogen lamp with quartz) in an instrument from Bentham Instruments Ltd [the abscissa shows the wavelength in nanometres (nm); the ordinate shows the External Quantum Efficiency (EQE) in percent (%)].

### Example 11 (Disclosure)

### Solar cell Comprising the Conjugated Anthradithiophene Terpolymer of Formula (Ia)

A polymer-based device was prepared on an ITO (indium-tin oxide) coated glass substrate (Kintec Company—Hong Kong), previously subjected to a cleaning procedure operating as described in Example 8.

The deposition of the cathodic buffer layer and the deposition of the anodic buffer layer were carried out as described in Example 8; the composition of said cathodic buffer layer and the composition of said anodic buffer layer are the same as the ones in Example 8; the thickness of said cathodic buffer layer and the thickness of said anodic buffer layer are the same as the ones in Example 8.

The active layer comprising the conjugated anthradithiophene terpolymer having formula (Ia) obtained as described in Example 6 and 2,2′-((2Z,2′Z)-((4,4,9,9-tetrahexyl-4,9-dihydro-s-indacene[1,2-b:5,6-b′]dithiophene-2,7- diyl)bis(methanilidene))bis(3-oxo-2,3-dihydro-1H-indene-2,1-diylidene))dimalononitrile (IDIC) (Sunatech) was deposited on the cathodic buffer layer thus obtained by spin coating of a 1:1 (v:v) solution in o-dichlorobenzene (Aldrich) with a concentration of conjugated anthradithiophene terpolymer having formula (Ia) equal to 9 mg/ml that had been kept at 100° C. under stirring overnight, operating at a rotation speed equal to 2000 rpm (acceleration equal to 2500 rpm/s), for 30 seconds. The thickness of the active layer was found to be 102 nm.

The deposition of the silver (Ag) anode was carried out as described in Example 8: the thickness of said silver anode (Ag) is the same as the one reported in Example 8.

The thicknesses were measured with a Dektak 150 (Veeco Instruments Inc.) profilometer.

The electrical characterization of the obtained device was carried out as described in Example 8: Table 2 shows the four characteristic parameters as average values.

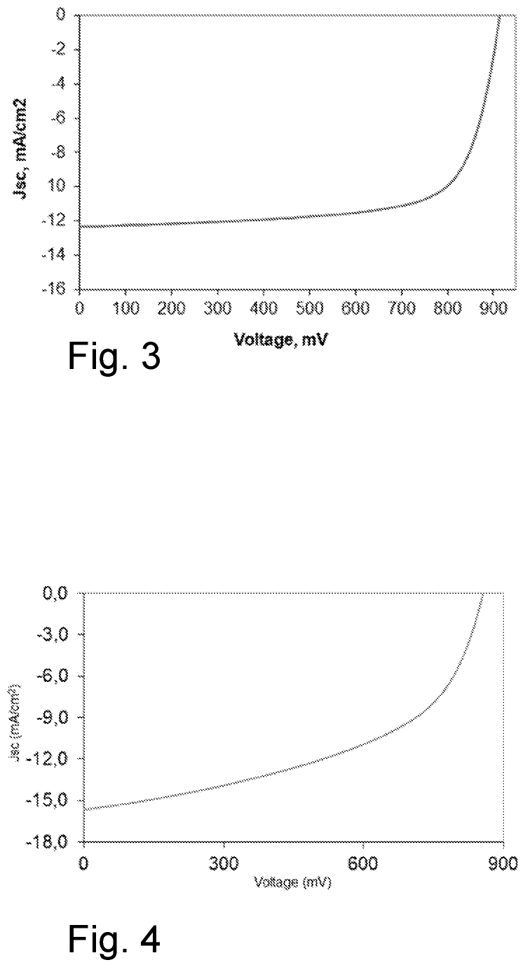

FIG. 3 shows the current-voltage curve (J-V) obtained [the abscissa shows the voltage in millivolts (mV); the ordinate shows the short circuit current density (Jsc) in milliampere/cm² (mA/cm²)].

### Example 12 (Disclosure)

### Solar Cell Comprising the Conjugated Anthradithiophene Terpolymer Having Formula (Ib)

A polymer-based device was prepared on an ITO (indium-tin oxide) coated glass substrate (Kintec Company—Hong Kong), previously subjected to a cleaning procedure operating as described in Example 8.

The deposition of the cathodic buffer layer and the deposition of the anodic buffer layer were carried out as described in Example 8; the composition of said cathodic buffer layer and the composition of said anodic buffer layer are the same as the ones in Example 8; the thickness of said cathodic buffer layer and the thickness of said anodic buffer layer are the same as the ones in Example 8.

The active layer, comprising the conjugated anthradithiophene terpolymer having formula (Ib) obtained as described in Example 7 and 3,9-bis(2-methylene-((3-(1,1-dicyanomethylene)-6,7-difluoro)-indanone))-5,5,11,11-tetrakis(4-hexyl-phenyl)-dithiene[2,3-d:2′,3′-d′]-s-indacene[1,2-b:5,6-b′]dithiophene (IT-4F) (Ossila), was deposited on the cathodic buffer layer thus obtained by spin coating of a 1:1 (v:v) solution in o-dichlorobenzene (Aldrich) with a concentration of anthradithiophenic conjugated terpolymer having formula (Ib) equal to 10 mg/ml which had been kept under stirring at 100° C. overnight, operating at a rotation speed equal to 2000 rpm (acceleration equal to 2500 rpm/s), for 30 seconds. The thickness of the active layer was found to be 102 nm.

The deposition of the silver (Ag) anode was carried out as described in Example 8: the thickness of said silver anode (Ag) is the same as the one reported in Example 8.

The thicknesses were measured with a Dektak 150 (Veeco Instruments Inc.) profilometer.

The electrical characterization of the obtained device was carried out as described in Example 8: Table 2 shows the four characteristic parameters as average values.

FIG. 4 shows the current-voltage curve (I-V) obtained [the abscissa shows the voltage in millivolts (mV); the ordinate shows the short circuit current density (Jsc) in milliampere/cm² (mA/cm²)].

FIG. 6 shows the curve relating to the External Quantum Efficiency (EQE) which was recorded under a monochromatic light (obtained using the TMc300E-U (I/C)—“Triple grating monochromator” and a double source with a Xenon lamp and a halogen lamp with quartz) in an instrument from Bentham Instruments Ltd [the abscissa shows the wavelength in nanometres (nm); the ordinate shows the External Quantum Efficiency (EQE) in percent (%)].

TABLE 2

| | | V_{OC}⁽²⁾ | J_{SC}⁽³⁾ | PCEₐᵥ⁽⁴⁾ |
|---|---|---|---|---|
| EXAMPLE | FF⁽¹⁾ | (V) | (mA/cm²) | (%) |
| 8 (comparative) | 0.57 | 0.56 | 10.10 | 3.30 |
| 9 (disclosure) | 0.61 | 0.86 | 8.31 | 4.37 |
| 10 (disclosure) | 0.63 | 0.86 | 15.69 | 8.52 |
| 11 (disclosure) | 0.72 | 0.92 | 12.35 | 8.09 |
| 12 (disclosure) | 0.49 | 0.86 | 15.13 | 6.40 |

⁽¹⁾FF (Fill Factor) is calculated according to the following equation:
$\frac{{V}_{MPP} \cdot {J}_{MPP}}{{V}_{OC} \cdot {J}_{SC}}$ wherein V_{MPP} and J_{MPP} are voltage and current density, respectively, corresponding to the point of maximum power, V_{OC} is the open circuit voltage and J_{SC} is the short circuit current density;
⁽²⁾V_{OC} is the open circuit voltage;
⁽³⁾J_{SC} is the short circuit current density;
⁽⁴⁾PCEₐᵥ is the device efficiency calculated according to the following equation:
$\frac{{V}_{OC} \cdot {J}_{SC} \cdot FF}{{P}_{in}}$ wherein V_{OC}, J_{SC} and FF have the same meanings reported above and Pᵢₙ is the intensity of the incident light on the device.

1. A conjugated anthradithiophene terpolymer having general formula (I): 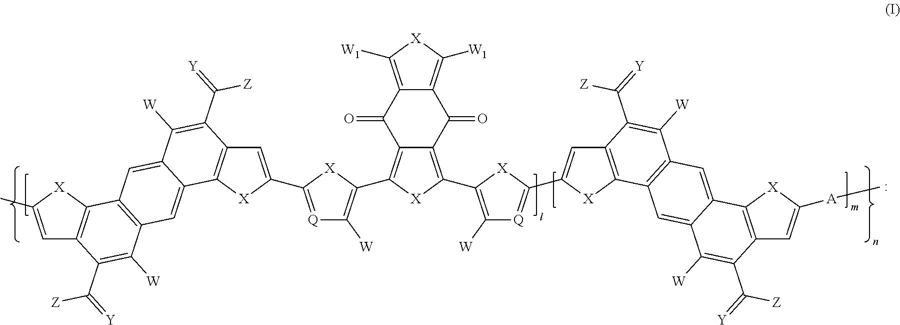
wherein
Q, equal or different from each other, represent a nitrogen atom; or they are selected from C—R₁ groups wherein R₁ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
W, equal or different from each other, represent a hydrogen atom; or they are selected from C₁-C₂₀ alkyl groups, preferably C₂-C₁₀, linear or branched;
W₁, equal or different from each other, represent a hydrogen atom; or they are selected from C₁-C₂₀ alkyl groups, preferably C₂-C₁₀, linear or branched;
X, equal or different from each other, represent a sulfur atom, an oxygen atom, a selenium atom;
Y, equal or different from each other, represent an oxygen atom, a sulfur atom;
Z, equal or different from each other, are selected from amino groups —N—R₂R₃ wherein R₂ represents a hydrogen atom, or is selected from C₁-C₂₀, preferably C₂-C₁₀, linear or branched alkyl groups, or is selected from optionally substituted cycloalkyl groups and R₃ is selected from C₁-C₂₀ alkyl groups, preferably C₂-C₁₀, linear or branched, or is selected from optionally substituted cycloalkyl groups; or they are selected from —O—R₄ groups wherein R₄ is selected from C₁-C₃₀ alkyl groups, preferably C₂-C₂₄, linear or branched, optionally substituted cycloalkyl groups, optionally substituted aryl groups, optionally substituted heteroaryl groups; or they are selected from R₅—O—[CH₂—CH₂—O]ₙ₁-polyethyleneoxy groups wherein R₅ is selected from C₁-C₂₀ alkyl groups, preferably C₂-C₁₀, linear or branched, and n1 is an integer ranging from 1 to 4; or they are selected from —R₆—OR₇ groups wherein R₆ is selected from C₁-C₂₀ alkylene groups, preferably C₂-C₁₀, linear or branched and R₇ represents a hydrogen atom or is selected from C₁-C₂₀ alkyl groups, preferably C₂-C₁₀, linear or branched; or they are selected from R₅—[—OCH₂—CH₂—]ₙ₁-polyethyleneoxy groups wherein R₅ has the same meanings reported above and n1 is an integer ranging from 1 to 4; or they are selected from R—S-thiol groups wherein R is selected from C₁-C₂₀, preferably C₂-C₁₀, linear or branched alkyl groups;
A represents an electron-acceptor group; an electron-donor group; or is selected from optionally substituted aryl groups, optionally substituted heteroaryl groups;
l and m, equal or different from each other, represent an integer ranging from 1 to 9; and
n is an integer ranging from 10 to 500.

2. The conjugated anthradithiophenic terpolymer having general formula (I) according to claim 1, wherein said group A is selected from the groups reported in Table 1:
TABLE 1 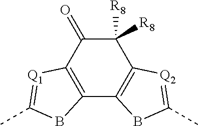 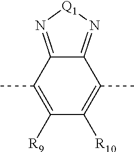 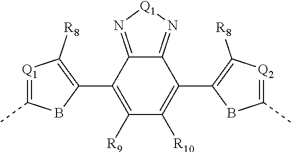 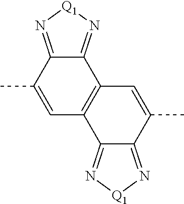 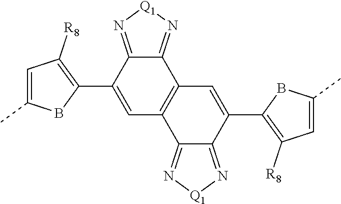 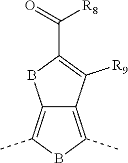 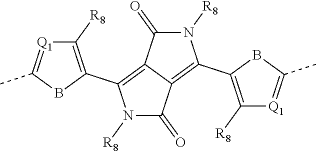 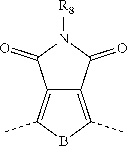 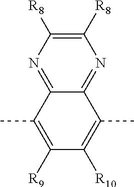 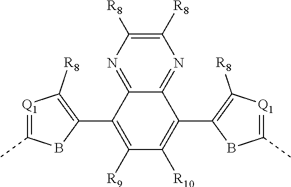 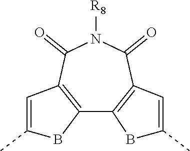 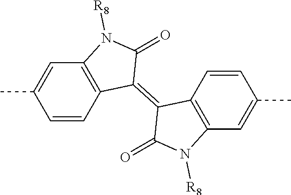 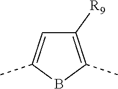 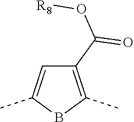 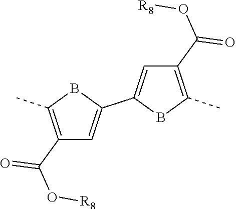 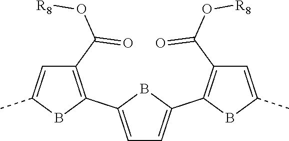 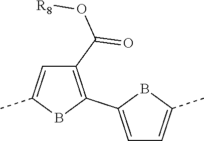
wherein:
B represents a sulfur atom, an oxygen atom, a selenium atom, or is selected from N—R₁₁ groups wherein R₁₁ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
Q₁ and Q₂, equal or different from each other, represent a nitrogen atom, a sulfur atom, an oxygen atom, a selenium atom; or they are selected from C—R₁₂ groups wherein R₁₂ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups;
R₈, equal or different from each other, are selected from C₁-C₂₀ alkyl groups, preferably C₂-C₁₀, linear or branched, optionally halogenated, optionally substituted cycloalkyl groups, optionally substituted aryl groups, optionally substituted heteroaryl groups, C₁-C₂₀ alkoxyl groups, preferably C₂-C₁₀, linear or branched; or they are selected from polyethyleneoxy groups R₁₃—[—OCH₂—CH₂—]ₙ— wherein R₁₃ is selected from C₁-C₂₀ alkyl groups, preferably C₂-C₁₀, linear or branched, and n is an integer ranging from 1 to 4; or they are selected from —R₁₄—OR₁₄ groups wherein R₁₄ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups; or they are selected from —COO—R₁₅ groups wherein R₁₅ represents a hydrogen atom, or is selected from C₁-C₂₀ alkyl groups, preferably C₂-C₁₀, linear or branched, optionally substituted cycloalkyl groups, optionally substituted aryl groups, optionally substituted heteroaryl groups; or represent a —CHO group, or a cyano group (—CN); and
R₉ and R₁₀, equal or different from each other, represent a hydrogen atom, a fluorine atom, a chlorine atom; or they are selected from C₁-C₂₀ alkyl groups, preferably C₂-C₁₀, linear or branched, optionally substituted cycloalkyl groups, optionally substituted aryl groups, C₁-C₂₀ alkoxyl groups, preferably C₂-C₁₀, linear or branched; or they are selected from polyethyleneoxy groups R₁₃—[—OCH₂—CH₂—]ₙ— in which R₁₃ has the same meanings reported above and n is an integer ranging from 1 to 4; or they are selected from —R₁₄—OR₁₄ groups wherein R₁₄ has the same meanings reported above; or they are selected from —COR₁₅ groups in which R₁₅ has the same meanings reported above; or they are selected from —COO—R₁₅ groups in which R₁₅ has the same meanings reported above; or they represent a —CHO group, or a cyano group (—CN);
or, R₉ and R₁₀, can optionally be bonded together so as to form, together with the carbon atoms to which they are bonded, a cycle or a polycyclic system containing from 3 to 14 carbon atoms, preferably from 4 to 6 carbon atoms, saturated, unsaturated, or aromatic, optionally containing one or more heteroatoms such as oxygen, sulfur, nitrogen, silicon, phosphorus, selenium.

3. The conjugated anthradithiophene terpolymer having general formula (I) according to claim 1, wherein
Q represents a C—R₁ group wherein R₁ represents a hydrogen atom;
W, equal to each other, represent a hydrogen atom;
W₁, equal to each other, represent a C₁-C₂₀ alkyl group, linear or branched, preferably are a 2-ethylhexyl group;
X, equal to each other, represent a sulfur atom;
Y, equal to each other, represent an oxygen atom;
Z, equal to each other, represent a —O—R₄ group wherein R₄ represents a linear or branched C₁-C₃₀ alkyl group, preferably are a 2-octyldodecyloxy group; and
A represents an electron-acceptor group or an electron-donor group wherein B represents a sulfur atom, Q₁ and Q₂, equal to each other, represent a C—R₁₂ group wherein R₁₂ is selected from C₁-C₂₀ alkyl groups, preferably is an octyl, R₉ and R₁₀, equal to each other, represent a fluorine atom; or represents an electron-acceptor group or an electron-donor group wherein B represents a sulfur atom and R₈ is selected from linear or branched C₁-C₂₀ alkyl groups, optionally halogenated, preferably is trifluoroethyl.

4. A photovoltaic device (or solar device) such as a photovoltaic cell (or solar cell), a photovoltaic module (or solar module), either on a rigid support or on a flexible support, comprising at least one conjugated anthradithiophenic terpolymer having general formula according to claim 1.
